(19) United States
(12) Patent Application Publication
(10) Pub. No.: US 2008/0251121 A1
(43) Pub. Date: Oct. 16, 2008

(54) Oxynitride passivation of solar cell

(76) Inventor: Charles Stone, Cedar Park, TX (US)

Correspondence Address: Okamoto & Benedicto LLP, P.O. Box 641330, San Jose, CA, 95164-1330, US

(21) Appl. No.: 11/786,916

(22) Filed: Apr. 12, 2007

(51) Int. Cl. H01L 31/0216; H01L 31/09

(52) U.S. Cl. 136/256; 438/71; 438/80; 257/E31.093

(57) ABSTRACT

One embodiment relates to a structure for a solar cell. The structure includes a silicon substrate with P-type and N-type active diffusion regions therein. An oxynitride passivation layer is included at least over the P-type and N-type active diffusion regions. The structure further includes contact openings through the oxynitride passivation layer to the P-type and N-type active diffusion regions, and metal grid lines which selectively contact the P-type and N-type active diffusion regions by way of the contact openings. Another embodiment relates to a method of fabricating a solar cell. Other embodiments, aspects and features are also disclosed.

### BACKGROUND OF THE INVENTION

1. Field of the Invention

The present invention relates generally to solar cells, and more particularly to solar cell structures and fabrication processes.

2. Description of the Background Art

Solar cells are devices for converting solar radiation to electrical energy. They may be fabricated on a semiconductor wafer using semiconductor processing technology. Generally speaking, a solar cell may be fabricated by forming P-type and N-type active diffusion regions in a silicon substrate. Solar radiation impinging on the solar cell creates electrons and holes that migrate to the active diffusion regions, thereby creating voltage differentials between the active diffusion regions. In a back side contact solar cell, both the active diffusion regions and the metal grids coupled to them are on the back side of the solar cell. The metal grids allow an external electrical circuit to be coupled to and be powered by the solar cell.

One problem or limitation with solar cells is that their performance tends to degrade over time. In other words, solar cells tend to get less reliable and less efficient over time. Applicant believes that the present disclosure provides a solution which overcomes, or at least partially overcomes, the performance degradation problem in solar cells.

### SUMMARY

One embodiment relates to a structure for a solar cell. The structure includes a silicon substrate with P-type and N-type active diffusion regions therein. An oxynitride passivation layer is included at least over the P-type and N-type active diffusion regions. The structure further includes contact openings through the oxynitride passivation layer to the P-type and N-type active diffusion regions, and metal grid lines which selectively contact the P-type and N-type active diffusion regions by way of the contact openings.

Another embodiment relates to a method of fabricating a solar cell. P-type and N-type active diffusion regions are formed in a silicon substrate, and an oxynitride passivation layer is formed at least over the P-type and N-type active diffusion regions. In addition, contact openings are formed through the oxynitride passivation layer to the P-type and N-type active diffusion regions, and metal grid lines are formed which selectively contact the P-type and N-type active diffusion regions by way of the contact openings.

Other embodiments, aspects and features are also disclosed.

These and other features of the present invention will be readily apparent to persons of ordinary skill in the art upon reading the entirety of this disclosure, which includes the accompanying drawings and claims.

### DESCRIPTION OF THE DRAWINGS

Note that the use of the same reference label in different drawings indicates the same or like components. Drawings are not necessarily to scale unless otherwise noted.

FIG. 1 is a schematic cross-sectional diagram of a silicon wafer for use in fabricating a solar cell structure in accordance with an embodiment of the invention.

FIG. 2 is a schematic cross-sectional diagram of the silicon wafer after deposition of doping sources in accordance with an embodiment of the invention.

FIG. 3A is a schematic cross-sectional diagram of the silicon wafer after heating in a furnace to diffuse dopants into the wafer in accordance with an embodiment of the invention.

FIG. 3B is a schematic cross-sectional diagram of the silicon wafer after heating in a furnace wherein the layer dopant sources is now shown as an oxide or glass layer in accordance with an embodiment of the invention.

FIG. 4 is a schematic cross-sectional diagram of the silicon wafer after growing an oxynitride passivation layer on front and back sides in accordance with an embodiment of the invention.

FIG. 5 is a schematic cross-sectional diagram of the silicon wafer after forming contact openings in the oxynitride passivation layer on the back side in accordance with an embodiment of the invention.

FIG. 6 is a schematic cross-sectional diagram of the silicon wafer after depositing a metal layer in accordance with an embodiment of the invention.

FIG. 7 is a schematic cross-sectional diagram of the silicon wafer after patterning the metal layer in accordance with an embodiment of the invention.

FIG. 8A is a schematic diagram of a method of fabricating a solar cell with an oxynitride passivation layer in accordance with an embodiment of the invention.

FIG. 8B is a schematic diagram of a method of fabricating a solar cell with an oxynitride passivation layer in accordance with another embodiment of the invention.

### DETAILED DESCRIPTION

In the present disclosure, numerous specific details are provided, such as examples of structures and fabrication steps, to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

As discussed above, solar cells tend to get less reliable and less efficient over time. Applicant believes that at least part of this degradation is caused by the exposure of the solar cells to damp heat over time. Applicant further believes that such damp heat causes moisture to diffuse through the passivation layer on the device side of the solar cell.

Applicant believes that the present disclosure provides a solar cell structure, and method of manufacturing same, which prevents or reduces the diffusion of moisture through the passivation layer on the device side of the solar cell. As such, applicant believes that solar cells fabricated in accordance with embodiments of the invention will have less performance degradation over time. Solar cells manufactured according to the present disclosure should be better at maintaining reliability and efficiency under damp heat conditions.

As described further below, applicant has come up with modified processes to fabricate a solar cell structure so as to incorporate an oxynitride passivation layer in order to better shield the devices from the effects of moisture diffusion. Applicant further believes that the oxynitride layer will improve device performance by reducing surface recombination.

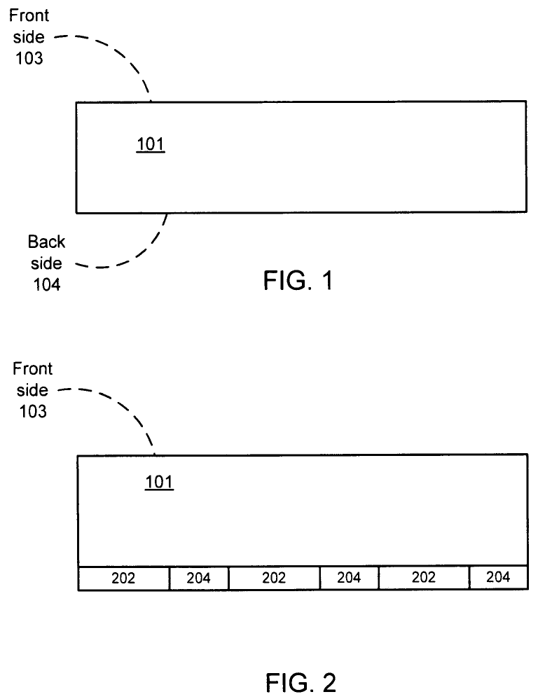

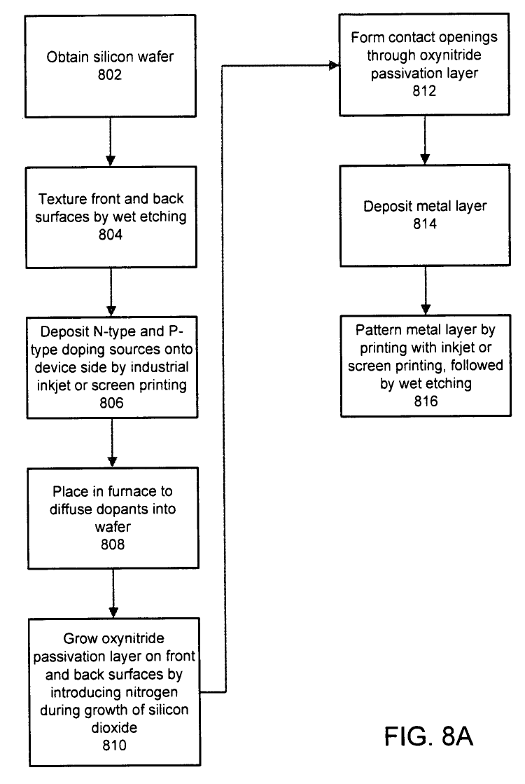

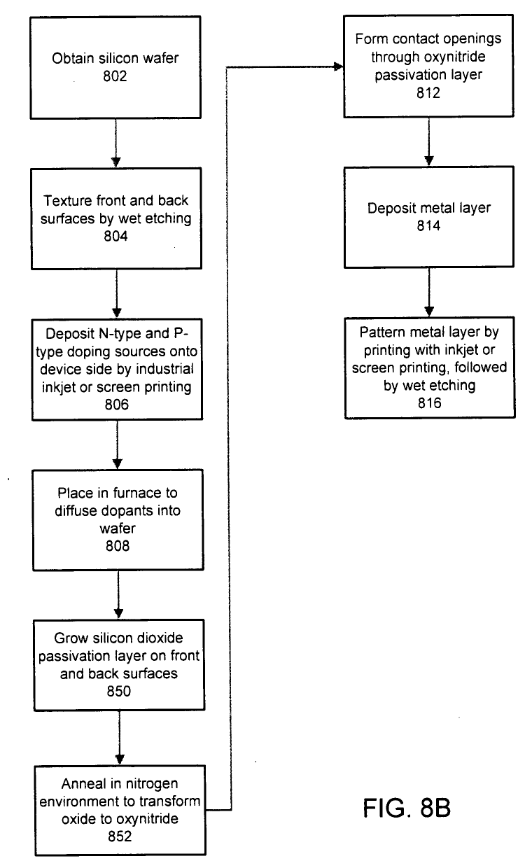

FIGS. 1 through 7 provide cross-sectional diagrams of a silicon substrate at various points in a modified fabrication process In accordance with an embodiment of the invention. FIGS. 8A and 8B provide flow charts showing steps in two potential fabrication processes in accordance with embodiments of the invention.

FIG. 1 is a schematic cross-sectional diagram of a silicon wafer 101 for use in fabricating a solar cell structure in accordance with an embodiment of the invention. The wafer 101 may comprise, for example, an N-type silicon wafer. As shown in FIG. 1, a front side 103 and a back side 104 of the wafer are denoted.

It may be desirable in the fabrication process to texture the front side 103 and the back side 104 by a wet etch process, for example, using potassium hydroxide an isopropyl alcohol. Texturing the front side 103 may be advantageous in improving the solar radiation collection efficiency.

FIG. 2 is a schematic cross-sectional diagram of the silicon wafer 101 after deposition of doping sources (202 and 204) on the back side 104 in accordance with an embodiment of the invention. The dopant sources 202 and 204 may be selectively deposited in that they are not formed by blanket deposition followed by patterning. The dopant sources 202 and 204 may be selectively deposited by directly printing them on the back side 104 of the wafer, for example, using industrial inkjet printing or screen printing. For example, if industrial injet printing is used, then the dopant sources 202 and 204 may be discharged by different print heads or different groups of nozzles of a same print head. The dopant sources 202 and 204 may be printed in one pass or multiple passes of one or more print heads. Suitable materials for inkjet printing of dopant sources may include appropriately doped combination of solvent (for instance, isopropyl alcohol), organo siloxane, and a catalyst, while suitable materials for screen printing of dopant sources may include an appropriately doped combination of solvent, organo siloxane, catalyst, and fillers (such as Al₂O₃, TiO₂, or SiO₂ particles).

The first dopant source 202 may comprise an N-type dopant, such as phosphorus. The second dopant source 204 may comprise a P-type dopant, such as boron. In one implementation, the dopant concentration in each dopant source may be uniform or substantially uniform. In another implementation, the dopant concentration in each dopant source may vary according to a concentration profile. Such a concentration profile may be accomplished by dividing each doping source region into multiple sub-regions to be printed, each sub-region having a heavier (N+ or P+) or lighter (N− or P−) concentration of dopants.

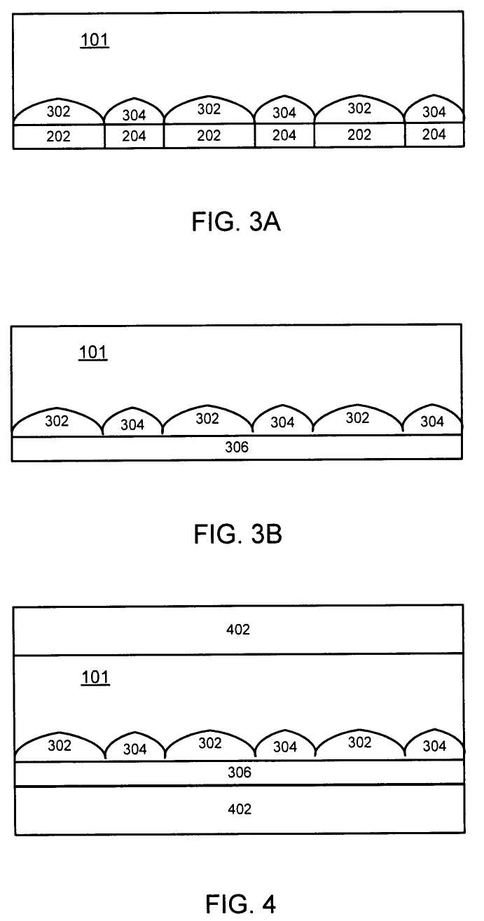

The dopants are diffused from the dopant sources (202 and 204) into the silicon wafer 101 by placing the wafer 101 in a furnace. FIG. 3A is a schematic cross-sectional diagram of the silicon wafer 101 after heating in a furnace to diffuse dopants into the wafer in accordance with an embodiment of the invention. As shown, the diffusion step results in the diffusion of N-type dopants from the dopant sources 202 into the wafer 101 to form N+ active diffusion regions 302. The diffusion step also results in the diffusion of P-type dopants from the dopant sources 204 into the wafer 101 to form P+ active diffusion regions 304. After the diffusion step, the layer of dopant sources (202/204) becomes an oxide or glass layer 306 which is depicted in FIG. 3B. This layer 306 may be considered as an initial passivation layer to protect the side with the devices (here, the back side).

In accordance with an embodiment of the invention, the next step or steps may be performed so as to provide an oxynitride passivation layer 402. As mentioned above, applicant believes that such an oxynitride passivation layer 402 slows or prevents the diffusion of moisture into the solar cell substrate and, hence, provides for less performance degradation over time for the solar cell. It is believed that the oxynitride passivation layer 402 is superior to preventing deleterious effects of moisture diffusion in comparison to the conventional silicon dioxide passivation layer. It is further believed that the oxynitride layer will improve device performance by reducing surface recombination.

FIG. 4 is a schematic cross-sectional diagram of the silicon wafer after growing an oxynitride passivation layer 402 on front and back sides in accordance with an embodiment of the invention. As described further below in relation to FIGS. 8A and 8B, the oxynitride passivation layer 402 may be grown by either introducing nitrogen gas into a furnace during the growth of silicon dioxide (see block 810 in FIG. 8A), or by annealing the wafer in a nitrogen environment after the oxide growth (see blocks 850 and 852 in FIG. 8B).

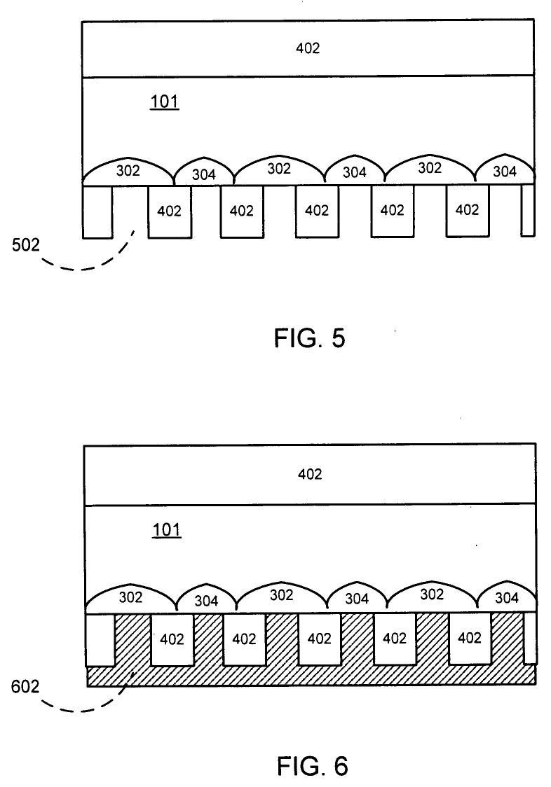

FIG. 5 is a schematic cross-sectional diagram of the silicon wafer after forming contact openings 502 in the oxynitride passivation layer 402 on the back side 104 in accordance with an embodiment of the invention. For purposes of simplification, the initial passivation layer 306 is incorporated as part of the oxynitride passivation layer 402 in FIGS. 5 through 7. The contact openings 502 in FIG. 5 may be formed on the oxynitride passivation layer 402 on the back side 104 of the wafer, for example, by inkjet or screen printing of a mask, followed by wet etching.

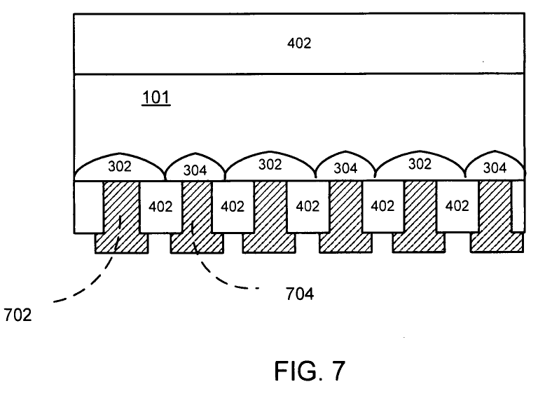

FIG. 6 is a schematic cross-sectional diagram of the silicon wafer after depositing a metal layer 602 in accordance with an embodiment of the invention. The metal layer 602 may comprise, for example, aluminum. The metal layer 602 may then be patterned, for example, by inkjet or screen printing of a mask, followed by wet etching. FIG. 7 is a schematic cross-sectional diagram of the silicon wafer after patterning the metal layer in accordance with an embodiment of the invention. The patterning may form metal grid lines on the back side of the wafer. Note that the metal grid lines are not apparent in the cross-sectional diagram of FIG. 7, but would be viewable in a two-dimensional planar view of the back side.

While FIGS. 1-7 show steps of a process for fabricating a back-side contact solar cell with an oxynitride passivation layer, other embodiments of the invention may relate to fabricating a front-side contact solar cell with an oxynitride passivation layer.

FIG. 8A is a schematic diagram of a method 800 of fabricating a solar cell with an oxynitride passivation layer in accordance with an embodiment of the invention. A silicon wafer is obtained (block 802). For example, the wafer may be an N-type (or alternatively a P-type) silicon wafer.

The front and back sides may be processed by wet etching so as to texture the surfaces (block 804). Texturing the front side may be advantageous in improving the solar radiation collection efficiency. In other processes, the front side may be textured by wet etching in a later process step. In some processes, the back side may be masked from the wet etching or be polished after the wet etching.

Doping sources (N-type and P-type) may be deposited on the device side (for example, the back side) (block 806). For example, the deposition may be performed by industrial ink jet printing or screen printing. Thereafter, the wafer may be placed in a furnace at high temperature so as to enable the dopants to diffuse from the sources into corresponding regions of the wafer (block 808).

The oxynitride passivation layer may then be grown on front and back surfaces by introducing nitrogen gas into the furnace during growth of silicon dioxide (block 810). In other words, the oxynitride layer may be grown in a furnace by introducing nitrogen gas, in addition to the conventional oxygen gas.

Therafter, contact openings may be formed through the oxynitride passivation layer on the device side of the wafer (block 812). Subsequently, a metal layer (for example, aluminum) may be deposited on the device side (block 814). The metal layer may then be patterned, for example, by printing with inkjet or screen printing, followed by wet etching (block 816).

FIG. 8B is a schematic diagram of a method of fabricating a solar cell with an oxynitride passivation layer in accordance with another embodiment of the invention. FIG. 8B differs from FIG. 8A in the process steps to form the oxynitride passivation layer. In FIG. 8B, the oxynitride passivation layer is formed by first growing a silicon dioxide passivation layer on front and back surfaces of the wafer (block 850). Thereafter, the wafer is annealed in a nitrogen environment to transform the oxide into oxynitride (block 852).

While certain pertinent steps are shown in the two example processes of FIGS. 8A and 8B and discussed above, the fabrication of solar cells may, of course, include various alternate and/or additional steps. Furthermore, while the above description focuses on back side contact solar cell embodiments (wherein the contacts are on the back side which is away from the sunlight), front side contact solar cell embodiments are also contemplated and should similarly benefit from the oxynitride passivation layer disclosed herein.

While specific embodiments of the present invention have been provided, it is to be understood that these embodiments are for illustration purposes and not limiting. Many additional embodiments will be apparent to persons of ordinary skill in the art reading this disclosure.

What is claimed is:

1. A method of fabricating a solar cell, the method comprising:
forming P-type and N-type active diffusion regions in a silicon substrate;
forming an oxynitride passivation layer over the P-type and N-type active diffusion regions;
forming contact openings through the oxynitride passivation layer to the P-type and N-type active diffusion regions; and
forming metal grid lines which selectively contact the P-type and N-type active diffusion regions by way of the contact openings.

2. The method of claim 1, wherein forming the oxynitride passivation layer comprises growing the oxynitride passivation layer in an environment including oxygen and nitrogen gases.

3. The method of claim 1, wherein forming the oxynitride passivation layer comprises growing an oxide layer, followed by annealing in an environment with nitrogen gas so as to transform the oxide layer to an oxynitride layer.

4. The method of claim 1, further comprising texturing a front surface of the silicon substrate to increase solar collection efficiency.

5. The method of claim 1, wherein the P-type and N-type active diffusion regions are formed by deposition of doping sources, followed by diffusion of dopants from the doping sources into the diffusion regions.

6. The method of claim 5, wherein the doping sources are deposited by direct printing.

7. The method of claim 5, wherein the oxynitride passivation layer is deposited over the doping sources.

8. The method of claim 1, wherein surface recombination during operation of the solar cell is reduced by the oxynitride passivation layer.

9. The method of claim 1, wherein the oxynitride passivation layer is formed on both front and back sides of the silicon substrate.

10. A structure for a solar cell comprising:
a silicon substrate;
P-type and N-type active diffusion regions in the silicon substrate;
an oxynitride passivation layer over the P-type and N-type active diffusion regions;
contact openings through the oxynitride passivation layer to the P-type and N-type active diffusion regions; and
metal grid lines which selectively contact the P-type and N-type active diffusion regions by way of the contact openings.

11. The structure of claim 10, wherein the oxynitride passivation layer is grown in an environment including oxygen and nitrogen gases.

12. The structure of claim 10, wherein the oxynitride passivation layer is formed by growing an oxide layer, followed by annealing in an environment with nitrogen gas so as to transform the oxide layer to an oxynitride layer.

13. The structure of claim 10, further comprising a textured front surface of the silicon substrate to increase solar collection efficiency.

14. The structure of claim 10, wherein the P-type and N-type active diffusion regions are formed by deposition of doping sources, followed by diffusion of dopants from the doping sources into the diffusion regions.

15. The structure of claim 14, wherein the doping sources are deposited by direct printing.

16. The structure of claim 14, wherein the oxynitride passivation layer is deposited over the doping sources.

17. The structure of claim 10, wherein surface recombination during operation of the solar cell is reduced by the oxynitride passivation layer.

18. The structure of claim 10, wherein the oxynitride passivation layer is formed on both front and back sides of the silicon substrate.
